(19) United States
(12) Patent Application Publication
(10) Pub. No.: US 2026/0143944 A1
(43) Pub. Date: May 21, 2026

(54) DISPLAY PANEL AND DISPLAY DEVICE

(71) Applicant: HKC CORPORATION LIMITED, SHENZHEN (CN)

(72) Inventors: Yao LI, SHENZHEN (CN); Lidan YE, SHENZHEN (CN)

(73) Assignee: HKC CORPORATION LIMITED, SHENZHEN (CN)

(21) Appl. No.: 19/369,326

(22) Filed: Oct. 27, 2025

(30) Foreign Application Priority Data
Oct. 31, 2024 (CN) 202411552732.1

(51) Int. Cl. H10K 59/38; H10K 59/122; H10K 59/80; H10K 102/00

(52) U.S. Cl. CPC H10K 59/38; H10K 59/122; H10K 59/80517; H10K 59/873; H10K 2102/351

(57) ABSTRACT

A display panel and a display device. The display panel includes: a drive substrate, a pixel definition layer, multiple light-emitting units, an encapsulation layer, and a first light conversion layer; the pixel definition layer protrudes from the drive substrate and forms open regions; the multiple light-emitting units are disposed within the open regions; the encapsulation layer is disposed on a side of the pixel definition layer away from the drive substrate; the encapsulation layer includes multiple inclined portions that are inclined relative to the drive substrate, with the multiple inclined portions each facing a corresponding non-open region; the first light conversion layer is disposed on a surface of each inclined portion away from the pixel definition layer; the incident light beam includes an invisible light, and the first light conversion layer is configured to convert at least a portion of the invisible light into a visible light for emission.

### CROSS-REFERENCE TO RELATED APPLICATIONS

The present application claims priority of Chinese Patent Application No. 202411552732.1, filed on Oct. 31, 2024, the entire contents of which are hereby incorporated by reference in their entirety.

### TECHNICAL FIELD

The present disclosure relates to the field of display technologies, and in particular to a display panel and a display device.

### BACKGROUND

Organic Light Emitting Diode (OLED), also referred to as Organic Electroluminesence Display (OELD), represents a cutting-edge advancement in display technology. Its advantages, such as superior contrast ratios, wide viewing angles, flexibility, lightweight design, and energy efficiency, surpass those of traditional liquid crystal displays (LCDs), making OLED a widely adopted and promising direction in modern display innovation.

However, the luminous brightness of existing OLED display panels is still required to be further improved.

### SUMMARY OF THE DISCLOSURE

The present disclosure provides a display panel, including a drive substrate, a pixel definition layer, multiple light-emitting units, an encapsulation layer, and a first light conversion layer; the pixel definition layer is disposed on the drive substrate, the pixel definition layer protrudes from the drive substrate and forms open regions; the multiple light-emitting units are disposed within the open regions, each light-emitting unit including a first electrode, a light-emitting layer, and a second electrode that are stacked; the encapsulation layer is disposed on a side of the pixel definition layer and the multiple light-emitting units away from the drive substrate; the encapsulation layer includes multiple inclined portions that are inclined relative to the drive substrate, with the multiple inclined portions each facing a corresponding non-open region; the first light conversion layer is disposed on a surface of each inclined portion away from the pixel definition layer; the first light conversion layer is configured to receive at least a portion of an incident light beam; where the incident light beam includes an invisible light, and the first light conversion layer is configured to convert at least a portion of the invisible light into a visible light for emission.

The present disclosure further provides a display device including the display panel as above.

### BRIEF DESCRIPTION OF THE DRAWINGS

To more clearly illustrate the technical solutions of the embodiments of the present disclosure, the following is a brief introduction to the drawings used in the description of the embodiments. It should be understood that the drawings described below are merely some embodiments of the present disclosure. For those skilled in the art, other drawings can be obtained without any creative effort based on these drawings.

FIG. 1 is a structural schematic view of a display device according to some embodiments of the present disclosure.

FIG. 2 is a first structural schematic view of a display panel according to some embodiments of the present disclosure.

FIG. 3 is a second structural schematic view of a display panel according to some embodiments of the present disclosure.

FIG. 4 is a third structural schematic view of a display panel according to some embodiments of the present disclosure.

### DETAILED DESCRIPTION

The technical solutions in the embodiments of the present disclosure will be described in detail with reference to the accompanying drawings. The following embodiments are provided solely to illustrate the technical solutions of the present disclosure and are therefore only examples and should not be intended to limit the scope of the present disclosure.

Unless otherwise defined, all technical and scientific terms used herein have the same meanings as generally understood by those skilled in the art to which the present disclosure relates. The terms used herein are intended to describe specific embodiments and are not intended to limit the present disclosure. The terms “include” and “have” and any variations thereof used in the description, claims, and accompanying drawings of the present disclosure are intended to cover non-exclusive inclusion.

In the description of the embodiments of the present disclosure, the technical terms “first”, “second”, etc. are only intended to distinguish different objects, and are not to be construed as indicating or implying relative importance, or implicitly specifying the number, specific order, or primary and secondary relationship of the technical features indicated. In the description of the embodiments of the present disclosure, “more than one” means more than two, unless otherwise expressly and specifically limited.

Reference to “embodiments” herein implies that a particular feature, structure, or characteristic described in conjunction with an embodiment may be included in at least one embodiment of the present disclosure. The presence of the phrase at various points in the specification does not necessarily refer to the same embodiments or to separate or alternative embodiments that are mutually exclusive of other embodiments. It is understood by those skilled in the art, both explicitly and implicitly, that the embodiments described herein may be combined with other embodiments.

In the description of embodiments of the present disclosure, the term “and/or” is merely an associative relationship describing an associated object, indicating that three types of relationships may exist, such as A and/or B, which may indicate: the existence of A alone, the existence of both A and B, and the existence of B alone. In addition, the character “/” herein generally indicates that the associated objects are in an “or” relationship.

In the description of the embodiments of the present disclosure, the term “plurality” refers to more than two (including two), and similarly, “multiple groups” refers to more than two (including two), and “multiple tablets” refers to more than two (including two).

In the description of embodiments of the present disclosure, the technical terms “center”, “longitudinal”, “transverse”, “length”, “width”, “thickness”, “up”, “down”, “front”, “rear”, “left”, “right”, “vertical”, “horizontal”, “top”, “bottom”, “inside”, “outside”, “clockwise”, “counterclockwise”, “axial”, “radial”, “peripheral”, etc. indicate orientations or positional relationships based on those shown in the accompanying drawings, and are intended only to facilitate the description of the embodiments of the present disclosure and to simplify the description, and are not intended to indicate or imply that the device or element referred to must have a particular orientation, be constructed and operated with a particular orientation, and therefore are not to be construed as a limitation of the embodiments of the present disclosure.

In the description of the embodiments of the present disclosure, unless otherwise expressly provided and limited, the technical terms “mounted”, “connected”, “coupled”, “fixed”, and the like shall be understood in a broad sense, for example, it may be a fixed connection, a detachable connection, or a one-piece connection; it may be a mechanical connection, or an electrical connection; it may be a direct connection, or an indirect connection through an intermediate medium, and it may be a connectivity within the two elements or an interactive relationship between the two elements. For those skilled in the art, the specific meanings of the above terms in the embodiments of the present disclosure may be understood on a case-by-case basis.

Organic Light Emitting Diode (OLED), also referred to as Organic Electroluminesence Display (OELD), represents a cutting-edge advancement in display technology. Its advantages, such as superior contrast ratios, wide viewing angles, flexibility, lightweight design, and energy efficiency, surpass those of traditional liquid crystal displays (LCDs), making OLED a widely adopted and promising direction in modern display innovation.

However, the luminous brightness of existing OLED display panels is still required to be further improved.

The present disclosure provides a display device, and the display device may include, but is not limited to, a mobile phone, a tablet, a laptop, a desktop, a terminal, an interactive display, a digital audio/video device, an Internet of Things (IoT) device, and the like. The interactive display may include an interactive whiteboard, a digital advertising interactive screen, and a gaming interactive display, etc. The IoT device may include a smart home device and a smart wearable device, etc. The display device may include a display panel, and the display device may display images and other functions through the display panel.

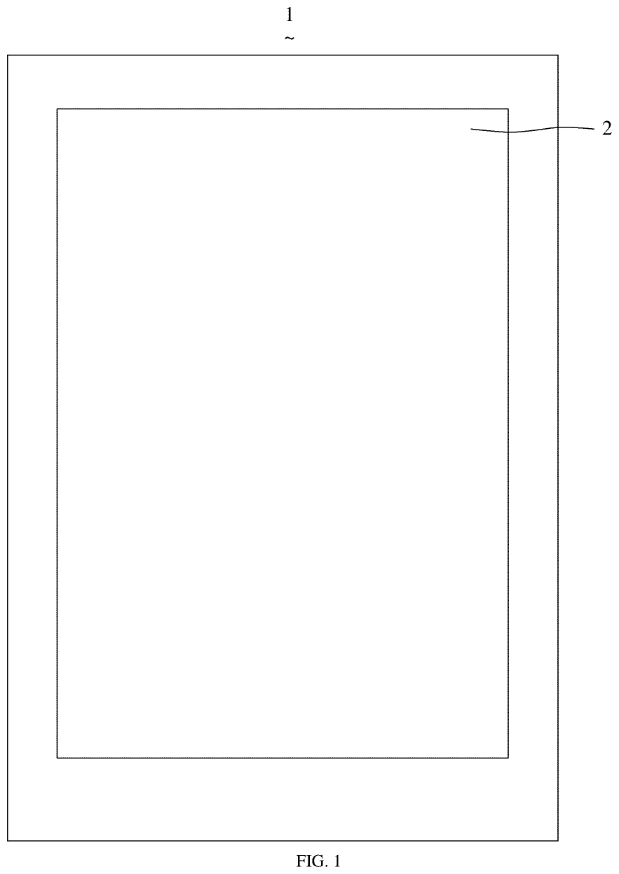

Referring to FIG. 1, FIG. 1 is a structural schematic view of a display device according to some embodiments of the present disclosure.

The display device 1 may include, but is not limited to, mobile phones, computers, etc., where the mobile phone may be an ordinary mobile phone, a feature phone, or a smartphone, and the smartphone may be a flat-screen phone, a curved-screen phone, or a foldable phone, etc. The display device 1 is arranged with a display panel 2, and the display panel 2 may be disposed on a head portion or a middle portion or a tail portion of the display device 1. The display panel 2 may be configured to display information of the display device 1, for example, the display panel 2 may serve as a visual information display portion of the display device 1. The display panel 2 may further serve as a touch information input portion, for facilitating a user's operation of the display device 1 by means of touching the display panel 2, e.g., for realizing the displaying and inputting requirements for interface navigation and function switching of the display device 1.

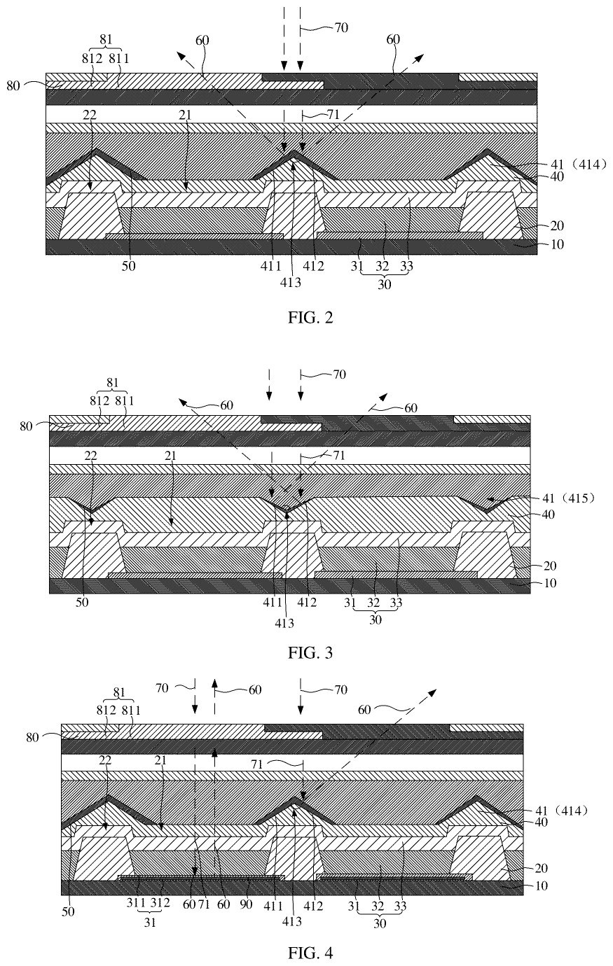

Referring to FIGS. 2-4, FIG. 2 is a first structural schematic view of a display panel according to some embodiments of the present disclosure, FIG. 3 is a second structural schematic view of a display panel according to some embodiments of the present disclosure, and FIG. 4 is a third structural schematic view of a display panel according to some embodiments of the present disclosure.

To solve the above problems, the present disclosure provides a display panel 2, which includes: a drive substrate 10, a pixel definition layer 20, multiple light-emitting units 30, an encapsulation layer 40, and a first light conversion layer 50; the pixel definition layer 20 is disposed on the drive substrate 10, the pixel definition layer 20 protrudes from the drive substrate 10 and forms open regions 21; the multiple light-emitting units 30 are disposed within the open regions 21, each light-emitting unit 30 including a first electrode 31, a light-emitting layer 32, and a second electrode 33 that are stacked; the encapsulation layer 40 is disposed on a side of the pixel definition layer 20 and the multiple light-emitting units 30 away from the drive substrate 10; the encapsulation layer 40 includes multiple inclined portions 41 inclined relative to the drive substrate 10, with the multiple inclined portions 41 each facing a corresponding non-open region 22; the first light conversion layer 50 is disposed on a surface of each inclined portion 41 away from the pixel definition layer 20; the first light conversion layer 50 is configured to receive at least a portion of an incident light beam 70; where the incident light beam 70 includes an invisible light 71, and the first light conversion layer 50 is configured to convert at least a portion of the invisible light 71 into a visible light 60 for emission.

The drive substrate 10 is configured to drive the multiple light-emitting units 30 to emit light. The drive substrate 10 may include, but is not limited to, a silicon-based drive substrate 10, a glass-based drive substrate 10, etc. For example, in a case of the silicon-based drive substrate 10, the silicon-based drive substrate 10 may include a silicon-based substrate and a drive circuit layer, with the drive circuit layer being disposed on a surface of the silicon-based substrate. The silicon substrate refers to a substrate plate based on a monocrystalline silicon material. The drive circuit layer includes active drive circuit (not shown) integrated on the silicon-based substrate using a Complementary Metal-Oxide-Semiconductor (CMOS) process.

The pixel definition layer 20 protrudes from the drive substrate 10 and forms open regions 21, and the multiple light-emitting units 30 are disposed in the open regions 21. The pixel definition layer 20 may define the positions of the light-emitting units 30 through the open region 21, such that the light-emitting units 30 are provided in suitable positions. The material of the pixel definition layer 20 may be one of an organic material, an organic material with an inorganic coating provided thereon, or an inorganic material. The organic material of the pixel definition layer 20 includes, but is not limited to, polyimide. The inorganic material of the pixel definition layer 20 includes, but is not limited to, silicon oxide (SiO₂), silicon nitride (Si₃N₄), silicon nitride oxide (Si₂N₂O), magnesium fluoride (MgF₂), or a combination thereof. The specific material of the pixel-definition layer 20 is not limited and is selected according to actual needs. As a result, adjacent light-emitting units 30 may be isolated by the pixel-definition layer 20, thereby reducing the risk of crosstalk between the multiple light-emitting units 30.

The light-emitting layer 32 of the light-emitting unit 30 may emit light beams in an energized state, and the light-emitting layers 32 of the multiple light-emitting units 30 have different light-emitting colors. For example, each of the light-emitting layers 32 emits one of red light, blue light, and green light when energized. The first electrode 31 and the second electrode 33 are configured to energize the light-emitting layer 32, and exemplarily, the first electrode 31 may be an anode electrode and the second electrode 33 may be a cathode electrode.

The encapsulation layer 40 covers a side of the light-emitting units 30 and the pixel definition layer 20 away from the drive substrate 10. The encapsulation layer 40 provides encapsulation and protection for the light-emitting units 30 and the pixel definition layer 20. The material of the encapsulation layer 40 may include, but is not limited to, inorganic materials, organic materials, or a combination thereof. No specific material is prescribed for the encapsulation layer 40 herein. The inclined portion 41 is inclined relative to the drive substrate 10. It should be noted that a surface of the inclined portion 41 away from the pixel definition layer 20 is inclined relative to the drive substrate 10. The inclination may refer to at least a portion of the surface of the inclined portion 41 being neither perpendicular nor parallel to the drive substrate 10. The inclined portion 41 is disposed in correspondence with and facing the non-open region 22. It can be understood that the inclined portion 41 is disposed between corresponding adjacent two light-emitting units 30 to reduce obstruction of the light-emitting units 30.

The first light conversion layer 50 is disposed on a surface of the inclined portion 41 away from the pixel definition layer 20. The first light conversion layer 50 can receive at least a portion of the incident light beam 70. The incident light beam 70 is ambient light that is emitted into the interior of the display panel 2 from the exterior of the display panel 2, where the incident light beam 70 may be natural light, such as sunlight, etc., or artificial light, such as light beams emitted from external light emitting devices. It is to be understood that the incident light beam 70 may include a variety of wavelengths. The incident light beam 70 includes the invisible light 71, such as infrared light, ultraviolet (UV) light, high-energy rays, and the like, and it is to be noted that the invisible light 61 that is invisible for the human eye, such as ultraviolet light, cannot be directly used to compensate for the luminance of the display panel 2, whereas the first light conversion layer 50 may convert at least some of the invisible light 71 into the visible light 60 visible to the human eye. Exemplarily, the light conversion layer 50 may be an aerogel.

For example, Prof. Haibo ZHAO, from the team of academician Yuzhong WANG in the State Local Joint Engineering Laboratory of Environmentally Friendly Polymer Materials of Sichuan University, proposed a new strategy for radiation cooling based on biomass intrinsic photoluminescence, and developed an all-biomass radiation-cooling aerogel that has a high solar reflectivity and can be recycled. The biomass aerogel (GE/DNA) prepared from gelatin (GE) and DNA has unique fluorescent/phosphorescent properties as well as a highly ordered layered structure. This intrinsic photoluminescence effect allows the aerogel to convert absorbed UV light into visible light, effectively increasing the solar-weighted reflectance of the aerogel material in the visible region (up to 104.0% under sunlight simulation), thereby dramatically gaining the daytime radiative cooling efficiency of the aerogel material, and lowering the ambient temperature by up to 16.0° C. under the outdoor conditions of high solar irradiance. On the other hand, by utilizing the reversible dissociation-reconstruction of strong ionic hydrogen bonds at the water-mediated aerogel interface, the large-scale preparation of aerogel panels with anisotropic pore structure was achieved by a scalable and universal water welding strategy, and the long-range ordered pore structure ensures the reliability of the optical properties and comprehensive performance of the aerogel material. In addition, the all-biomass aerogel material is flame retardant, rapidly self-repairable, recyclable and biodegradable, and is highly environmentally friendly throughout the life cycle of material source, preparation, use and disposal.

It should be understood that when the first light conversion layer 50 converts the invisible light 71, such as ultraviolet light, into the visible light 60 for emission, due to the corresponding arrangement of the inclined portion 41 and the non-open region 22 that face each other, the first light conversion layer 50 emits the converted visible light 60 to the open region 21 and, together with the light beam emitted by the light-emitting unit 30, emits it outward, thereby achieving brightness compensation for the light-emitting unit 30 and enhancing the brightness of the display panel 2. It should be noted that the first light conversion layer 50 has good reflective properties, allowing the visible light 60 in the incident light beam 70 to be directly reflected by the first light conversion layer 50 and emitted outward together with the visible light 60 converted from the invisible light 71, in conjunction with the light beam emitted by the light-emitting unit 30.

Through the above implementations, the first light conversion layer 50 on the inclined portion 41 can receive the incident light beam 70 entering the display panel 2 from the outside and convert at least part of the invisible light 71 in the incident light beam 70 into the visible light 60 for emission. In this way, the incident light beam 70 can be fully utilized, with the invisible light 71 converted into the visible light 60 to compensate for the brightness of the light-emitting unit 30, thereby enhancing the brightness of the display panel 2. Additionally, if the ultraviolet light in the incident light beam 70 directly illuminates the internal film layers of the display panel 2, it may cause issues such as aging and overheating of the internal film layers. In response thereto, by converting the ultraviolet light into the lower-energy visible light 60 via the first light conversion layer 50, the risk of display panel 2 aging due to ultraviolet light is mitigated, thereby extending the service life of the display panel 2.

In some embodiments, the inclined portion 41 includes a first inclined surface 411 and a second inclined surface 412 that are angled relative to each other at an angle 413, and the first light conversion layer 50 covers the first inclined surface 411 and the second inclined surface 412. The first light conversion layer 50 on the first inclined surface 411 can emit the visible light 60 toward the open region 21 on a side facing the first inclined surface 411, and the second light conversion layer 90 on the second inclined surface 412 can emit the visible light 60 toward the open region 21 on a side facing the second inclined surface 412. For example, the incident light beam 70 entering the display panel 2 perpendicular to the non-open region 22 can arrive at the first light conversion layer 50 at a certain incident angle, and is emitted as the visible light 60 through the conversion and reflection of the first light conversion layer 50 into the open region 21. The formation of the first inclined surface 411 and the second inclined surface 412 may be varied. For example, the inclined portion 41 may be a protruding portion 414, which protrudes relative to the encapsulation layer 40 in the open region 21, and a side wall of the protruding portion 414 is configured to form the first inclined surface 411 and the second inclined surface 412; or, the inclined portion 41 may be a recess 415, which is recessed relative to the encapsulation layer 40 in the open region 21, and a side wall of the recess 415 is configured to form the first inclined surface 411 and the second inclined surface 412. Thus, the first light conversion layer 50 covers the first inclined surface 411 and the second inclined surface 412, thereby facilitating the first light conversion layer 50 to fully utilize the incident light beam 70 for brightness compensation for the light-emitting units 30 on two sides.

In some embodiments, the inclined portion 41 is a protruding portion 414, and the angle 423 is greater than 135° and less than or equal to 180°. The size of the angle 423 may be selected according to actual requirements. Specifically, the angle 423 may be, but is not limited to, 135°, 145°, 160°, 175°, 180°, etc. It should be noted that the inclined portion 41 is a protruding portion 414, and the protruding portion 414 has a first inclined surface 411 and a second inclined surface 412 that are inclined at an angle 413. A longitudinal cross-section of the protruding portion 414 may be approximately viewed as a triangle. It can be understood that as the angle 423 becomes less, the protruding portion 414 becomes steeper, and as the angle 423 becomes greater, the protrusion portion 414 is relatively flatter. Correspondingly, when the protrusion portion 414 is steeper, the viewing angle of the light-emitting unit 30 is less, and when the protrusion portion 414 is flatter, the viewing angle of the light-emitting unit 30 is greater. In this way, the size of the angle 423 may be adjusted according to actual requirements to meet the viewing angle requirements of the light-emitting unit 30.

In some embodiments, the display panel 2 further includes a color filter layer 80 disposed on a side of the encapsulation layer 40 away from the drive substrate 10. The color filter layer 80 includes multiple color filter portions 81 arranged in sequence, which are configured to filter the received light beams for emission. The color filter portions 81 may include a red filter portion, a green filter portion, and a blue filter portion, which are configured to select the color of light transmitted through the color filter layer 80 to form pixel units. Depending on the combination of the red filter portions, green filter portions, and blue filter portions for each pixel, the color of the light can be easily adjusted, enabling the display panel 2 to display images with rich colors. Each color filter portion 81 is arranged in correspondence with and facing a light-emitting unit 30 of the same light-emitting color. For example, the red filter portion is arranged in correspondence with and facing the red light-emitting unit 30, the green filter portion is arranged in correspondence with and facing the green light-emitting unit 30, and the blue filter portion is arranged in correspondence with and facing the blue light-emitting unit 30. It should be noted that at least a portion of the invisible light 71 in the incident light beam 70, such as ultraviolet light, can pass through the color filter portions 81 into the display panel 2.

In some embodiments, the colors of adjacent color filter portions 81 are different, and at least part of the adjacent color filter portions 81 are stacked in the non-open region 22. For example, the color filter portions 81 may be arranged in a sequence of red, green, and blue, with at least a portion of the red filter portion and at least a portion of the green filter portion being stacked in a corresponding non-open region 22, and at least a portion of the green filter portion and at least a portion of the blue filter portion also being stacked in a corresponding non-open region 22. It should be noted that the red filter portion blocks the visible light 60 other than red, and the green filter portion blocks the visible light 60 other than green. When the red filter portion and the green filter portion are stacked, they block the visible light 60 in the incident light beam 70 and allow the invisible light 71, such as ultraviolet light, in the incident light beam 70 to be transmitted into the display panel 2. In this way, by stacking the adjacent two color filter portions 81 such that at least part of each is stacked in the non-open region 22, the visible light 60 is blocked from entering or exiting the display panel 2 through the non-open region 22. Compared to a filtering method where a black matrix is embedded in the color filter layer 80, it facilitates the entry of the invisible light 71 such as ultraviolet light into the display panel 2 through the non-open region 22, enabling the first light conversion layer 50 to fully utilize the invisible light 71 and convert it into the visible light 60 for brightness compensation, thereby enhancing the display brightness of the display panel 2. Taking a natural light incident vertically from the non-open region 22 as an example, the natural light, which includes the invisible light 71 such as ultraviolet light and various colored visible lights 60, is filtered by the color filter layer 80 and incident into the interior of the display panel 2. The color filter layer 80 in the non-open region 22 blocks all the visible light 60 and allows only the invisible light 71, including ultraviolet light, to enter the display panel 2. The ultraviolet light travels along a direction perpendicular to the drive substrate 10 and reaches the first light conversion layer 50 on the inclined portion 41, where it is converted into visible light 60 and emitted through the open region 21, combining with the light beams emitted from the light-emitting units 30 to outward, thereby enhancing the brightness of the display panel 2.

In some embodiments, each color filter portion 81 includes a main portion 811 and two extension portions 812, with the two extension portions 812 located on both ends of the main portion 811 in an arrangement direction of the multiple color filter portions 81. The main portion 811 is arranged in correspondence with and facing the open region 21, and the two adjacent color filter portions 81 have their extension portions 812 stacked in the non-open region 22. For example, one of the two extension portions 812 of the red filter portion may be stacked with one of the extension portions 812 of the green filter portion, and the other of the two extension portions 812 of the red filter portion may be stacked with one of the extension portions 812 of the blue filter portion. The thickness of the extension portion 812 may be less than the thickness of the main portion 811. In some embodiments, the sum of the thicknesses of the two overlapping extension portions 812 of adjacent color filter portions 81 may be equal to the thickness of the main portion 811, which may facilitate the connection of the multiple color filter portions 81, improve the thickness uniformity of the color filter layer 80, and thereby enhance the color uniformity of the display panel 2.

In some embodiments, the thickness of the first light conversion layer 50 is greater than or equal to 0.4 μm and less than or equal to 0.6 μm. For example, the thickness of the first conversion layer may be in a range from 0.4 to 0.5 μm, or from 0.5 to 0.6 μm, or from 0.45 to 0.55 μm. Specifically, the thickness of the first light conversion layer 50 may be 0.4 μm, 0.45 μm, 0.5 μm, 0.55 μm, 0.6 μm, etc., and more specifically, the thickness of the first light conversion layer 50 may be 0.5 μm. This may facilitate the first light conversion layer 50 to fully utilize the incident light beam 70 to compensate for the brightness of the display panel 2.

In some embodiments, the display panel 2 further includes a second light conversion layer 90, the first electrode 31 is a transparent electrode, and the second light conversion layer 90 is disposed on the first electrode 31. The second light conversion layer 90 is configured to receive the incident light beam 70 and convert at least a portion of the invisible light 71 in the incident light beam 70 into a visible light 60 for emission. The material of the second light conversion layer 90 may be similar to or the same as the material of the first light conversion layer 50. It can be understood that the first electrode 31 is disposed in the open region 21 and is a transparent electrode. The incident light beam 70 can be transmitted through the first electrode 31 to the second light conversion layer 90, thereby facilitating the second light conversion layer 90 to receive the incident light beam 70 entering the open region 21 and convert the invisible light 71 in the incident light beam 70 into the visible light 60 for emission. In addition, the second light conversion layer 90 can reflect and emit a portion of the light beams emitted by the light-emitting layer 32 and the visible light 60 in the incident light beam 70 entering the open region 21, thereby compensating for the brightness of the light-emitting unit 30 and improving the brightness of the display panel 2.

In some embodiments, the first electrode 31 includes a first conductive layer 311 and a second conductive layer 312 arranged at intervals, with the second light conversion layer 90 disposed between the first conductive layer 311 and the second conductive layer 312. For example, the first conductive layer 311 and the second conductive layer 312 may be transparent conductive layers, and the material of them may include but is not limited to indium tin oxide (ITO), etc.

In summary, the present disclosure provides a display panel 2, including: a drive substrate 10, a pixel definition layer 20, multiple light-emitting units 30, an encapsulation layer 40, and a first light conversion layer 50; the pixel definition layer 20 is disposed on the drive substrate 10, the pixel definition layer 20 protrudes from the drive substrate 10 and forms open regions 21; the multiple light-emitting units 30 are disposed within the open regions 21, each light-emitting unit 30 including a first electrode 31, a light-emitting layer 32, and a second electrode 33 that are stacked; the encapsulation layer 40 is disposed on a side of the pixel definition layer 20 and the multiple light-emitting units 30 away from the drive substrate 10; the encapsulation layer 40 includes multiple inclined portions 41 that are inclined relative to the drive substrate 10, with the multiple inclined portions 41 each facing a corresponding non-open region 22; the first light conversion layer 50 is disposed on a surface of each inclined portion 41 away from the pixel definition layer 20; the first light conversion layer 50 is configured to receive at least a portion of an incident light beam 70; where the incident light beam 70 includes an invisible light 71, and the first light conversion layer 50 is configured to convert at least a portion of the invisible light 71 into a visible light 60 for emission. Through the above implementations, the first light conversion layer 50 on the inclined portion 41 can receive the incident light beam 70 entering the display panel 2 from the outside and convert at least part of the invisible light 71 in the incident light beam 70 into a visible light 60 for emission. In this way, the incident light beam 70 can be fully utilized, with the invisible light 71 converted into the visible light 60 to compensate for the brightness of the light-emitting unit 30, thereby enhancing the brightness of the display panel 2.

Finally, it should be noted that the above embodiments are only intended to illustrate the technical solutions of the present disclosure, not to limit them. Although the present disclosure has been described in detail with reference to the foregoing embodiments, those skilled in the art should understand that he or she can still make modifications to the technical solutions documented in the foregoing embodiments, or make equivalent substitutions for some or all of the technical features therein. These modifications or substitutions do not detach the essence of the corresponding technical solutions from the scope of the technical solutions of the embodiments of the present disclosure, which shall be covered by the scope of the claims and the specification of the present disclosure. In particular, as long as there is no structural conflict, the technical features mentioned in the various embodiments can be combined in any way. The present disclosure is not limited to the particular embodiments disclosed herein, but includes all technical solutions falling within the scope of the claims.

1. A display panel, comprising:
a drive substrate;
a pixel definition layer, disposed on the drive substrate; wherein the pixel definition layer protrudes from the drive substrate and forms a plurality of open regions and a plurality of non-open regions that are alternately distributed;
a plurality of light-emitting units, disposed within the plurality of open regions in a one-to-one correspondence; wherein each light-emitting unit comprises a first electrode, a light-emitting layer, and a second electrode that are stacked;
an encapsulation layer, disposed on a side of the pixel definition layer and the plurality of light-emitting units away from the drive substrate; wherein the encapsulation layer comprises a plurality of inclined portions that are inclined relative to the drive substrate, and each of the plurality of inclined portions faces a corresponding non-open region; and
a first light conversion layer, disposed on a surface of each inclined portion away from the pixel definition layer; wherein the first light conversion layer is configured to receive at least a portion of an incident light beam;
wherein the incident light beam comprises an invisible light, and the first light conversion layer is configured to convert at least a portion of the invisible light into a visible light for emission.

2. The display panel according to claim 1, wherein each inclined portion comprises a first inclined surface and a second inclined surface that are angled relative to each other at an angle, and the first light conversion layer covers the first inclined surface and the second inclined surface.

3. The display panel according to claim 2, wherein the inclined portion is a protruding portion, and the angle is greater than 135° and less than or equal to 180°.

4. The display panel according to claim 2, wherein the inclined portion is a recess.

5. The display panel according to claim 1, wherein the display panel further comprises a color filter layer disposed on a side of the encapsulation layer away from the drive substrate; the color filter layer comprises a plurality of color filter portions arranged in sequence, and each of the plurality of color filter portions is configured to filter a received light beam for emission.

6. The display panel according to claim 5, wherein the plurality of color filter portions comprises a red filer portion, a green filter portion, and a blue filter portion arranged in sequence, and each of the plurality of color filter portions is arranged in correspondence with and facing a corresponding light-emitting unit with a same color.

7. The display panel according to claim 5, wherein colors of each adjacent two color filter portions of the plurality of color filter portions are different; at least a portion of one of the adjacent two color filter portions and at least a portion of the other of the adjacent two color filter portions are stacked in a corresponding non-open region.

8. The display panel according to claim 7, wherein each color filter portion comprises a main portion and two extension portions, with the two extension portions located on both ends of the main portion in an arrangement direction of the plurality of color filter portions; the main portion is arranged in correspondence with and facing a corresponding open region; for each adjacent two color filter portions of the plurality of color filter portions, one of the two extension portions of one of the adjacent two color filter portions and one of the two extension portions of the other of the adjacent two color filter portions are stacked in a corresponding non-open region.

9. The display panel according to claim 8, wherein the one of the two extension portions of the one of the adjacent two color filter portions has a first thickness, and the one of the two extension portions of the other of the adjacent two color filter portions has a second thickness; a sum of the first thickness and the second thickness is equal to a thickness of the main portion.

10. The display panel according to claim 1, wherein a thickness of the first light conversion layer is greater than or equal to 0.4 μm and less than or equal to 0.6 μm.

11. The display panel according to claim 1, further comprising a second light conversion layer; wherein the first electrode is a transparent electrode, and the second light conversion layer is disposed on the first electrode; the second light conversion layer is configured to receive the incident light beam and convert at least a portion of the invisible light in the incident light beam into the visible light for emission.

12. The display panel according to claim 11, wherein a material of the second light conversion layer is same as a material of the first light conversion layer.

13. The display panel according to claim 11, wherein the first electrode comprises a first conductive layer and a second conductive layer arranged at intervals, with the second light conversion layer disposed between the first conductive layer and the second conductive layer.

14. A display device, comprising a display panel; wherein the display panel comprises:
a drive substrate;
a pixel definition layer, disposed on the drive substrate; wherein the pixel definition layer protrudes from the drive substrate and forms a plurality of open regions and a plurality of non-open regions that are alternately distributed;
a plurality of light-emitting units, disposed within the plurality of open regions in a one-to-one correspondence; wherein each light-emitting unit comprises a first electrode, a light-emitting layer, and a second electrode that are stacked;
an encapsulation layer, disposed on a side of the pixel definition layer and the plurality of light-emitting units away from the drive substrate; wherein the encapsulation layer comprises a plurality of inclined portions that are inclined relative to the drive substrate, and each of the plurality of inclined portions faces a corresponding non-open region; and
a first light conversion layer, disposed on a surface of each inclined portion away from the pixel definition layer; wherein the first light conversion layer is configured to receive at least a portion of an incident light beam;
wherein the incident light beam comprises an invisible light, and the first light conversion layer is configured to convert at least a portion of the invisible light into a visible light for emission.

15. The display device according to claim 14, wherein each inclined portion comprises a first inclined surface and a second inclined surface that are angled relative to each other at an angle, and the first light conversion layer covers the first inclined surface and the second inclined surface.

16. The display device according to claim 15, wherein the inclined portion is a protruding portion, and the angle is greater than 135° and less than or equal to 180°.

17. The display device according to claim 14, wherein the display panel further comprises a color filter layer disposed on a side of the encapsulation layer away from the drive substrate; the color filter layer comprises a plurality of color filter portions arranged in sequence, and each of the plurality of color filter portions is configured to filter a received light beam for emission.

18. The display device according to claim 17, wherein colors of each adjacent two color filter portions of the plurality of color filter portions are different; at least a portion of one of the adjacent two color filter portions and at least a portion of the other of the adjacent two color filter portions are stacked in a corresponding non-open region.

19. The display device according to claim 18, wherein each color filter portion comprises a main portion and two extension portions, with the two extension portions located on both ends of the main portion in an arrangement direction of the plurality of color filter portions; the main portion is arranged in correspondence with and facing a corresponding open region; for each adjacent two color filter portions of the plurality of color filter portions, one of the two extension portions of one of the adjacent two color filter portions and one of the two extension portions of the other of the adjacent two color filter portions are stacked in a corresponding non-open region.

20. A display panel, comprising:
a drive substrate;
a pixel definition layer, disposed on the drive substrate and defining a plurality of open regions and a plurality of non-open regions; wherein each open region is configured to arrange a light-emitting unit;
an encapsulation layer, disposed on a side of the pixel definition layer away from the drive substrate; wherein the encapsulation layer comprises a plurality of inclined portions, and each inclined portion faces a corresponding non-open region; each inclined portion comprises two inclined surfaces away from the pixel definition layer that are angled relative to each other; and
a first light conversion layer, disposed on the two inclined surfaces of each inclined portion;
wherein the first light conversion layer is configured to receive at least a portion of an incident light beam;
wherein the incident light beam comprises an invisible light, and the first light conversion layer is configured to convert at least a portion of the invisible light into a visible light for emission.
